(19) United States
(12) Patent Application Publication
(10) Pub. No.: US 2023/0246081 A1
(43) Pub. Date: Aug. 3, 2023

(54) High Voltage MOSFET Device

(71) Applicant: NuVolta Technologies (Hefei) Co., Ltd., Hefei (CN)

(72) Inventors: John Lin, Carlsbad, CA (US); Wei Yue, Shanghai (CN); Yongjie Wu, Shanghai (CN)

(21) Appl. No.: 18/152,251

(22) Filed: Jan. 10, 2023

Related U.S. Application Data
(60) Provisional application No. 63/267,310, filed on Jan. 31, 2022.

(51) Int. Cl. H01L 29/40; H01L 29/78; H01L 21/265; H01L 29/66

(52) U.S. Cl. CPC H01L 29/402; H01L 29/7816; H01L 21/26513; H01L 29/401; H01L 29/66681

(57) ABSTRACT

An apparatus includes a substrate of a first conductivity, a drift layer of a second conductivity formed over the substrate, a body region of the first conductivity formed in the drift layer, a source region of the second conductivity formed in the body region, a drain region of the second conductivity formed in the drift layer, a gate dielectric layer formed over the body region and the drift layer, a gate formed over the gate dielectric layer, a first dielectric layer extending from a top surface of the drift layer to a top surface of the gate, and a field plate slit structure formed over the dielectric layer, wherein the field plate slit structure comprises a plurality of slits.

### PRIORITY

This application claims the benefit of U.S. Provisional Application No. 63/267,310, filed on Jan. 31, 2022, entitled “High Voltage MOSFET Device,” which application is hereby incorporated herein by reference.

### TECHNICAL FIELD

The present invention relates to a MOSFET device, and, in particular embodiments, to a high voltage MOSFET device including a structure having a plurality of field plate slits.

### BACKGROUND

As semiconductor technologies evolve, metal oxide semiconductor field effect transistors (MOSFET) have been widely used in integrated circuits. MOSFETs are voltage-controlled devices. When a control voltage is applied to the gate of a MOSFET and the control voltage is greater than the threshold of the MOSFET, a conductive channel is established between the drain and the source of the MOSFET. After the conductive channel has been established, a current flows between the drain and the source of the MOSFET. On the other hand, when the control voltage applied to the gate is less than the threshold of the MOSFET, the MOSFET is turned off accordingly.

MOSFETs may include two major categories, namely n-channel MOSFETs and p-channel MOSFETs. According to the structure difference, MOSFETs can be further divided into three sub-categories, planar MOSFETs, lateral double-diffused MOS (LDMOS) devices and vertical double-diffused MOSFETs. In comparison with other MOSFETs, the LDMOS device is capable of delivering more current per unit area because the asymmetric structure of the LDMOS device provides a short channel between the drain and the source of the LDMOS device. In order to further improve the performance (e.g., a high voltage MOSFET device), a lightly doped drift region is employed as a drain extension. Furthermore, the polysilicon gate of the LDMOS device is stretched beyond the channel region. More particularly, the polysilicon gate extends over a thick oxide layer to form a field plate to increase the breakdown voltage of the LDMOS device.

In a first implementation of the field plate, the thick oxide layer may be a shallow trench isolation (STI) region. The STI region is effective in increasing the breakdown voltage of the MOSFET device. However, the STI region may result in a higher on-resistance of the MOSFET device. In a second implementation of the field plate, the thick oxide layer may be an interlayer dielectric (ILD) layer. The drawback of the ILD layer is the thick ILD layer may not be effective in boosting the breakdown voltage of low-to-medium voltage MOSFET devices. It is desirable to have a simple and effective field plate to increase the breakdown voltage of the MOSFET device.

### SUMMARY

These and other problems are generally solved or circumvented, and technical advantages are generally achieved, by preferred embodiments of the present disclosure which provide a high voltage MOSFET device including a structure having a plurality of field plate slits.

In accordance with an embodiment, an apparatus comprises a substrate of a first conductivity, a drift layer of a second conductivity formed over the substrate, a body region of the first conductivity formed in the drift layer, a source region of the second conductivity formed in the body region, a drain region of the second conductivity formed in the drift layer, a gate dielectric layer formed over the body region and the drift layer, a gate formed over the gate dielectric layer, a first dielectric layer extending from a top surface of the drift layer to a top surface of the gate, and a field plate slit structure formed over the dielectric layer, wherein the field plate slit structure comprises a plurality of slits.

In accordance with another embodiment, a method comprises forming a gate over a substrate, forming a dielectric layer extending from a top surface of a drift layer to a top surface of the gate, forming an interlayer dielectric layer over the dielectric layer, etching the interlayer dielectric layer to form a plurality of openings in the interlayer dielectric layer, filling the plurality of openings with a conductive material to form a field plate slit structure and a plurality of contact plugs, wherein the field plate slit structure comprises a plurality of slits, and applying a planarization process to a top surface of the interlayer dielectric layer so as to remove excess materials.

In accordance with yet another embodiment, a device comprises a first drain/source region and a second drain/source region formed over a substrate, a gate formed over the substrate and between the first drain/source region and the second drain/source region, an interlayer dielectric layer formed over the gate, the first drain/source region and the second drain/source region, and a plurality of contact plugs and a field plate slit structure formed in the interlayer dielectric layer, wherein the field plate slit structure comprises a plurality of slits.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a simplified cross-sectional view of a high voltage MOSFET device having a field plate slit structure in accordance with various embodiments of the present disclosure;

FIG. 2 illustrates a simplified top view of a first implementation of the field plate slit structure of the high voltage MOSFET device shown in FIG. 1 in accordance with various embodiments of the present disclosure;

FIG. 3 illustrates a simplified top view of a second implementation of the field plate slit structure of the high voltage MOSFET device shown in FIG. 1 in accordance with various embodiments of the present disclosure;

FIG. 4 illustrates a simplified top view of a third implementation of the field plate slit structure of the high voltage MOSFET device shown in FIG. 1 in accordance with various embodiments of the present disclosure;

FIG. 5 illustrates a simplified top view of a fourth implementation of the field plate slit structure of the high voltage MOSFET device shown in FIG. 1 in accordance with various embodiments of the present disclosure;

FIG. 6 illustrates a simplified top view of a fifth implementation of the field plate slit structure of the high voltage MOSFET device shown in FIG. 1 in accordance with various embodiments of the present disclosure;

FIG. 7 illustrates a simplified top view of a sixth implementation of the field plate slit structure of the high voltage MOSFET device shown in FIG. 1 in accordance with various embodiments of the present disclosure;

FIG. 8 illustrates a simplified top view of a seventh implementation of the field plate slit structure of the high voltage MOSFET device shown in FIG. 1 in accordance with various embodiments of the present disclosure;

FIG. 9 illustrates a simplified top view of an eighth implementation of the field plate slit structure of the high voltage MOSFET device shown in FIG. 1 in accordance with various embodiments of the present disclosure;

FIG. 10 illustrates a simplified top view of a ninth implementation of the field plate slit structure of the high voltage MOSFET device shown in FIG. 1 in accordance with various embodiments of the present disclosure;

FIG. 11 illustrates a simplified top view of a tenth implementation of the field plate slit structure of the high voltage MOSFET device shown in FIG. 1 in accordance with various embodiments of the present disclosure;

FIG. 12 illustrates a simplified top view of an eleventh implementation of the field plate slit structure of the high voltage MOSFET device shown in FIG. 1 in accordance with various embodiments of the present disclosure; and

FIG. 13 illustrates a flow chart of a method for forming the high voltage MOSFET device shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to embodiments in a specific context, a high voltage MOSFET device including a structure having a plurality of field plate slits. The embodiments of the disclosure may also be applied, however, to a variety of metal oxide semiconductor field effect transistors (MOSFETs).

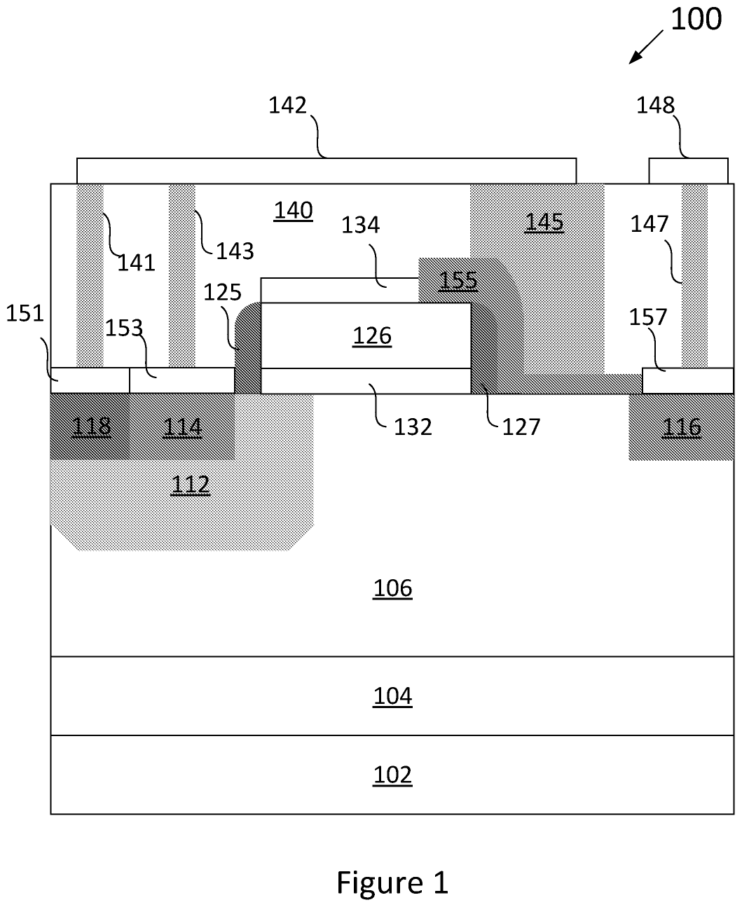

FIG. 1 illustrates a simplified cross-sectional view of a high voltage MOSFET device having a structure having a plurality of field plate slits in accordance with various embodiments of the present disclosure. The high voltage MOSFET device 100 include a substrate 102, a first layer 104, a drift layer 106 formed over the first layer 104, and a body region 112. The high voltage MOSFET device 100 further comprises a first drain/source region 114 and a body contact region 118 formed in the body region 112, a second drain/source region 116 formed in the drift layer 106, a gate dielectric layer 132, gate spacers 125, 127, a gate 126, a first silicide layer 151, a second silicide layer 153, a third silicide layer 134, a fourth silicide layer 157, a silicide block layer 155 and a field plate slit structure 145. The high voltage MOSFET device 100 further comprises a plurality of contact plugs including a body contact plug 141, a source contact plug 143 and a drain contact plug 147, and a first metallization layer including a first metal line 142 and a second metal line 148.

In some embodiments, the substrate 102, the body region 112 and the body contact region 118 have a first conductivity type. The drift layer 106, the first drain/source region 114 and the second drain/source region 116 have a second conductivity type. In some embodiments, the first conductivity type is p-type, and the second conductivity type is n-type. The high voltage MOSFET device 100 is an n-type transistor. Alternatively, the first conductivity type is n-type, and the second conductivity type is p-type. The high voltage MOSFET device 100 is a p-type transistor.

The substrate 102 may be formed of suitable semiconductor materials such as silicon, silicon germanium, silicon carbide and the like. Depending on different applications and design needs, the substrate 102 may be n-type or p-type. In some embodiments, the substrate 102 is a p-type substrate. Appropriate p-type dopants such as boron and the like are doped into the substrate 102. Alternatively, the substrate 102 is an n-type substrate. Appropriate n-type dopants such as phosphorous and the like are doped into the substrate 102.

The first layer 104 may comprise an epitaxial layer and a buried layer. In some embodiments, the epitaxial layer is a p-type layer. The buried layer is an n-type layer. The n-type buried layer is formed between the substrate 102 and the p-type epitaxial layer. The n-type buried layer is formed over the substrate 102 for isolation purposes. For example, the n-type buried layer is employed to prevent the current from flowing into the substrate 102, thereby avoiding the leakage in the high voltage MOSFET device 100. The p-type epitaxial layer is grown over the substrate 102. The epitaxial growth of the p-type epitaxial layer may be implemented by using any suitable semiconductor fabrication processes such as chemical vapor deposition (CVD) and the like. In some embodiments, the p-type epitaxial layer is of a doping density in a range from about 10¹⁴/cm³ to about 10¹⁶/cm³.

The drift layer 106 is an n-type layer formed over the first layer 104. In some embodiments, the drift layer 106 may be doped with an n-type dopant such as phosphorous to a doping density of about 10¹⁵/cm³ to about 10¹⁷/cm³. It should be noted that other n-type dopants such as arsenic, antimony, or the like, could alternatively be used. It should further be noted that throughout the description, the drift layer 106 may be alternatively referred to as an extended drain region.

The body region 112 is a p-type body region. The p-type body regions may be formed by implanting p-type doping materials such as boron and the like. In addition, a diffusion process may be used to form the p-type body region after the p-type doping materials have been implanted. In some embodiments, a p-type material such as boron may be implanted to a doping density of about 10¹⁶/cm³ to about 10¹⁸/cm³. The body region 112 may be alternatively referred to as a channel region.

The first drain/source region 114 is a first N+ region formed in the body region 112. The first drain/source region 114 may be alternatively referred to as the first N+ region 114. In accordance with an embodiment, the first N+ region 114 functions as a source region of the high voltage MOSFET device 100. The source region may be formed by implanting n-type dopants such as phosphorous and arsenic at a concentration of between about 10¹⁹/cm³ and about 10²⁰/cm³. As shown in FIG. 1, the source contact plug 143 is formed over the first N+ region 114.

The body contact region 118 is a P+ region formed in the body region 112. The body contact region 118 may be alternatively referred to as the P+ region 118. As shown in FIG. 1, the P+ region 118 is formed immediately adjacent to the first N+ region 114 in the body region 112. The P+ region 118 may be formed by implanting a p-type dopant such as boron at a concentration of between about 10¹⁹/cm³ and about 10²⁰/cm³. The P+ region 118 may contact the p-type body. In order to eliminate the body effect, the P+ region may be connected to the source region (the first N+ region 114) directly through the body contact plug 141, the first metal line 142 and the source contact plug 143.

The second drain/source region 116 is a second N+ region. The second drain/source region 116 may be alternatively referred to as the second N+ region 116. In accordance with an embodiment, the second N+ region 116 functions as a drain region of the high voltage MOSFET device 100. The second N+ region 116 may be formed by implanting n-type dopants such as phosphorous and arsenic at a concentration of between about 10¹⁹/cm³ and about 10²⁰/cm³. As shown in FIG. 1, the drain contact plug 147 is formed over the second N+ region 116.

The gate dielectric layer 132 is formed over the drift layer 106. In some embodiments, the gate dielectric layer 132 is of a thickness of between about 100 Angstroms and about 200 Angstroms. In some embodiments, the gate dielectric layer 132 may be formed of suitable oxide materials such as silicon oxide, silicon oxynitride, hafnium oxide, zirconium oxide or the like.

The gate 126 is formed on the gate dielectric layer 132. The gate 126 may be formed of polysilicon, polysilicon germanium, nickel silicide or other metal, metal alloy materials. As shown in FIG. 1, the gate 126 fully covers the channel region (the portion of the body region 112 between the first N+ region 114 and the drift layer 106). The gate 126 functions as a gate electrode configured to control the current flowing between the drain and source of the high voltage MOSFET device 100. The direction of the channel region is from the drain region 116 to the source region 114.

In order to form the gate spacers 125 and 127, a spacer layer is formed along sidewalls of the gate 126. The spacer layer may comprise suitable dielectric materials such as silicon nitride, oxynitride, silicon carbide, oxide and/or the like. The spacer layer may be formed by suitable deposition techniques such as atomic layer deposition (ALD), low-pressure chemical vapor deposition (LPCVD) and/or the like. The spacer layer may be patterned by suitable etching processes such as an anisotropic etching process and the like, thereby removing the unwanted portions of the spacer layer to form the gate spacers 125 and 127 as shown in FIG. 1.

Four silicide layers 151, 153, 134 and 157 are formed over the body contact region 118, the first drain/source region 114, the gate 126 and the second drain/source region 116, respectively as shown in FIG. 1. The silicide layers 151, 153, 134 and 157 are formed by a salicide process (also known as self-aligned silicide process). In the salicide process, a thin metal layer of blanket deposited over a semiconductor wafer having exposed active regions (e.g., body contact region 118, source region 114, gate 126 and drain region 116). The semiconductor wafer is then subjected to a plurality of annealing steps. This annealing process causes the metal of the thin metal layer to selectively react with the exposed silicon of the active regions, thereby forming metal silicide layers over the body contact region 118, the source region 114, the gate 126 and the drain region 116. In some embodiments, silicide layers 151, 153, 134 and 157 may comprise metals that react with silicon such as titanium, platinum, cobalt, any combinations thereof and the like.

The silicide block layer 155 is formed between the second drain/source region 116 and the gate 126. As shown in FIG. 1, a first portion of the silicide block layer 155 covers a portion of the top surface of the drift layer 106. A second portion of the silicide block layer 155 covers a sidewall of the gate spacer 127. A third portion of the silicide block layer 155 covers a portion of the top surface of the gate 126. As shown in FIG. 1, the silicide block layer 155 extends from the top surface of the drift layer 106 to the top surface of the gate 126. The silicide block layer 155 is a dielectric layer. More particularly, the silicide block layer 155 is formed of suitable dielectric materials such as silicon oxide materials and the like. The silicide block layer 155 is employed to cover a portion of the top surface of the gate 126 and a portion of the top surface of the drift layer 106 so as to prevent silicide formation on these two portions.

A dielectric layer 140 is formed over the substrate 102 as shown in FIG. 1. The dielectric layer 140 may be a low-k dielectric layer having a low dielectric constant. The dielectric layer 140 may also comprise a combination of materials such as silicon nitride, silicon oxy-nitride and the like. The dielectric layer 140 may be deposited using suitable deposition techniques such as sputtering, CVD and the like.

As shown in FIG. 1, the body contact plug 141, the source contact plug 143, the field plate slit structure 145 and the drain contact plug 147 are formed in the dielectric layer 140. In some embodiments, an anisotropic etching process is applied to the dielectric layer 140 to form a plurality of openings. Through a suitable fabrication process such as CVD, a suitable metal material is filled in the openings to form the body contact plug 141, the source contact plug 143, the field plate slit structure 145 and the drain contact plug 147. The metal material may be tungsten. Alternatively, the metal material may be any suitable conductive materials such as copper, titanium, aluminum, any combinations thereof and/or the like.

After the filling process finishes, a planarization process such as a chemical mechanical planarization (CMP) process may be applied to the top surface of the dielectric layer 140 so that the excess materials may be removed as a result. In the CMP process, a combination of etching materials and abrading materials are put into contact with the top surface of the dielectric layer 140 and a grinding pad is used to grind away the excess materials formed on top of the dielectric layer 140 until a planarized surface has been obtained.

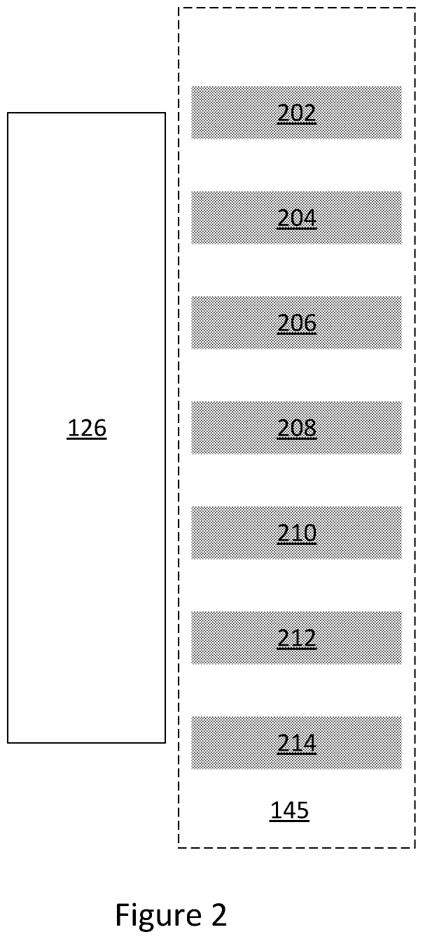

As shown in FIG. 1, the field plate slit structure 145 is formed over the silicide block layer 155. In some embodiments, one edge of the field plate slit structure 145 is aligned with a sidewall of the gate 126 as shown in FIG. 1. This field plate slit structure 145 helps to maintain the breakdown voltage of the high voltage MOSFET device 100. Furthermore, the field plate slit structure 145 helps to reduce the gate-to-drain overlap capacitance, thereby improving the switching performance of the high voltage MOSFET device 100. The detailed structure of the field plate slit structure 145 will be discussed below with respect to FIGS. 2-12.

In some embodiments, one or more inter-metal dielectric layers and the associated metallization layers may be formed over the dielectric layer 140. The inter-metal dielectric layers and the associated metallization layers are used to interconnect the electrical circuitry to each other and to provide an external electrical connection. For simplicity, FIG. 1 only illustrates a bottom metallization layer over the dielectric layer 140. As shown in FIG. 1, the bottom metallization layer comprises a first metal line 142 and a second metal line 148. Metal lines 142 and 148 are formed of suitable metal materials such as copper, aluminum, copper alloys, any combinations thereof and the like.

As shown in FIG. 1, the field plate slit structure 145 is electrically connected to the first drain/source region 114 (source region) through the first metal line 142, the source contact plug 143. In alternative embodiments, the field plate slit structure 145 may be electrically connected to the gate 126 through the first metal line 142 and a gate contact plug (not shown).

FIG. 2 illustrates a simplified top view of a first implementation of the field plate slit structure of the high voltage MOSFET device shown in FIG. 1 in accordance with various embodiments of the present disclosure. The field plate slit structure 145 is formed adjacent to the gate 126. The field plate slit structure 145 comprises seven slits. A first slit 202, a second slit 204, a third slit 206, a fourth slit 208, a fifth slit 210, a sixth slit 212 and a seventh slit 214 are in parallel. Each slit as shown in FIG. 2 is rectangular in shape. The longer side of each slit is oriented in the same direction as the channel of the high voltage MOSFET device shown in FIG. 1.

It should be noted that FIG. 2 illustrates only seven slits of the field plate slit structure that may include a plurality of such slits. The number of slits illustrated herein is limited solely for the purpose of clearly illustrating the inventive aspects of the various embodiments. The present disclosure is not limited to any specific number of slits.

In some embodiments, the width of each slit shown in FIG. 2 is the same as the standard width of a contact plug in a specific process node. For example, in the 0.18-micron (μm) process technology, the standard width of the contact plug is about 0.22 μm. The length of each slit is the same as the standard length of a contact field plate in the specific process node. The distance between two adjacent slits is the same as the standard spacing of contact plugs in the specific process node.

One advantageous feature of having the slits in FIG. 2 is that the slits are continuous in the direction the same as that of the channel of the high voltage MOSFET device shown in FIG. 1. Throughout the description, the direction of the channel is alternatively referred to as an X direction. The arrangement of the slits shown in FIG. 2 can automatically satisfies the maximum density in the X direction, thereby providing a breakdown voltage as good as a conventional contact field plate (e.g., a large contact field plate rectangular in shape). Furthermore, the manufacturing step of the slits shown in FIG. 2 is similar to that of the contact plugs (e.g., contact plugs 141, 143 and 147 shown in FIG. 1). In other words, the manufacturing step of the slits shown in FIG. 2 is compatible with the standard processing step. Such a compatible process helps to reduce the cost of semiconductor fabrication and increase the reliability of the high voltage MOSFET device.

It should be noted that the slits shown in FIG. 2 form a plurality of capacitor plates in parallel. Referring to FIG. 1, the field plate slit structure 145 including the slits shown in FIG. 2 is connected to a same voltage potential (e.g., the source region). Connecting the slits to a same voltage potential guarantees that the electric field does not exist in the direction orthogonal to the X direction of the high voltage MOSFET device. In addition, connecting the field plate slit structure 145 to the same voltage potential helps to shape the electric field in the X direction. As a result, the electric field in the X direction is similar to that of a standard contact field plate (a large contact field plate rectangular in shape).

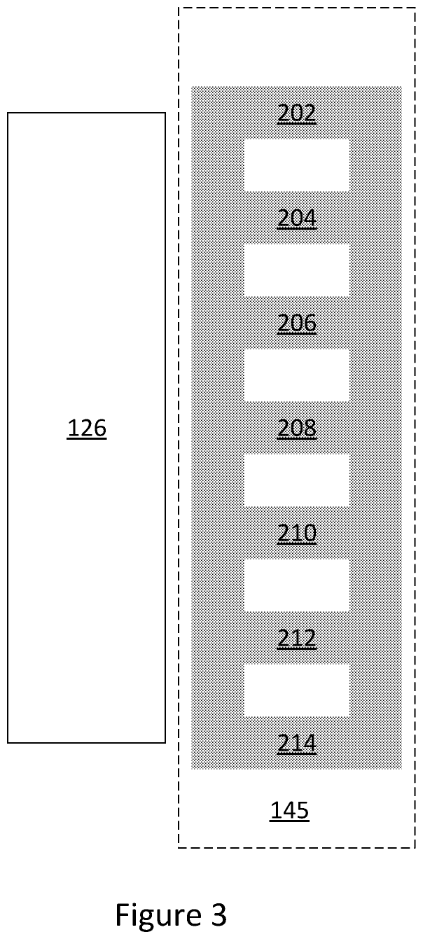

FIG. 3 illustrates a simplified top view of a second implementation of the field plate slit structure of the high voltage MOSFET device shown in FIG. 1 in accordance with various embodiments of the present disclosure. The field plate slit structure shown in FIG. 3 is similar to the field plate slit structure shown in FIG. 2 except that two connection bars are included to further improve the performance of the field plate slit structure 145. As shown in FIG. 3, a first connection bar is used to connect the left terminals of the seven slits 202-214. Likewise, a second connection bar is used to connect the right terminals of the seven slits 202-214. By employing these two connection bars, the seven slits 202-214 are electrically connected to each other. Referring back to FIG. 1, the field plate slit structure 145 is electrically connected to the source region 114 of the high voltage MOSFET device 100 through the first metallization layer (e.g., metal line 142). All seven slits have to be electrically connected to the first metallization layer. The layout of the first metallization layer is relatively complex. By employing these two connection bars, the seven slits are electrically connected to each other. As a result of electrically connecting these seven slits, the first metallization layer can be connected to the field plate slit structure 145 through a single point. Such a single point connection makes the layout of the first metallization layer more flexible.

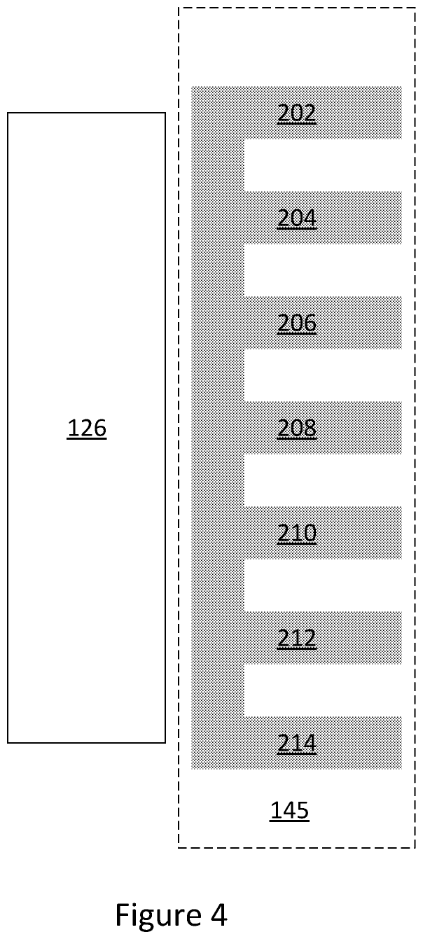

FIG. 4 illustrates a simplified top view of a third implementation of the field plate slit structure of the high voltage MOSFET device shown in FIG. 1 in accordance with various embodiments of the present disclosure. The field plate slit structure shown in FIG. 4 is similar to the field plate slit structure shown in FIG. 2 except that one connection bar is included to further improve the performance of the field plate slits. As shown in FIG. 4, the connection bar is used to connect the left terminals of the seven slits 202-214.

One advantageous feature of having the connection bar shown in FIG. 4 is that the electrically connected slits help to simplify the layout of the first metallization layer.

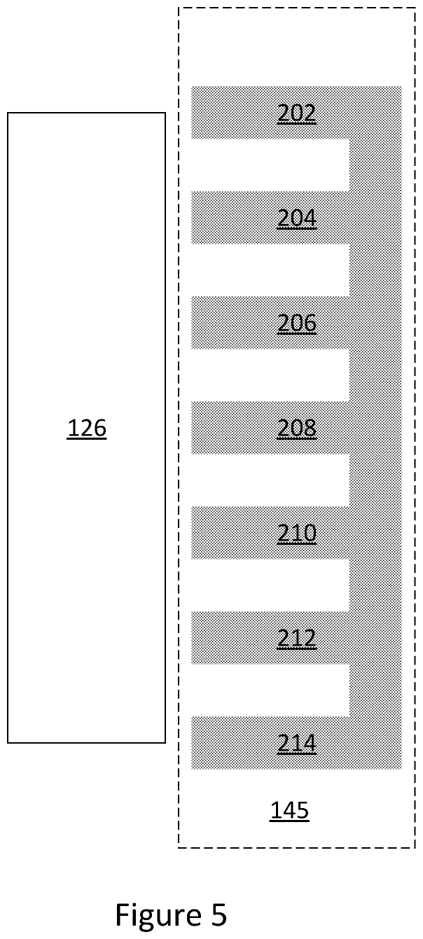

FIG. 5 illustrates a simplified top view of a fourth implementation of the field plate slit structure of the high voltage MOSFET device shown in FIG. 1 in accordance with various embodiments of the present disclosure. The field plate slit structure shown in FIG. 5 is similar to the field plate slit structure shown in FIG. 2 except that one connection bar is included to further improve the performance of the field plate slit structure. As shown in FIG. 5, a connection bar is used to connect the right terminals of the seven slits 202-214.

One advantageous feature of having the connection bar shown in FIG. 5 is that the electrically connected slits help to simplify the layout of the first metallization layer.

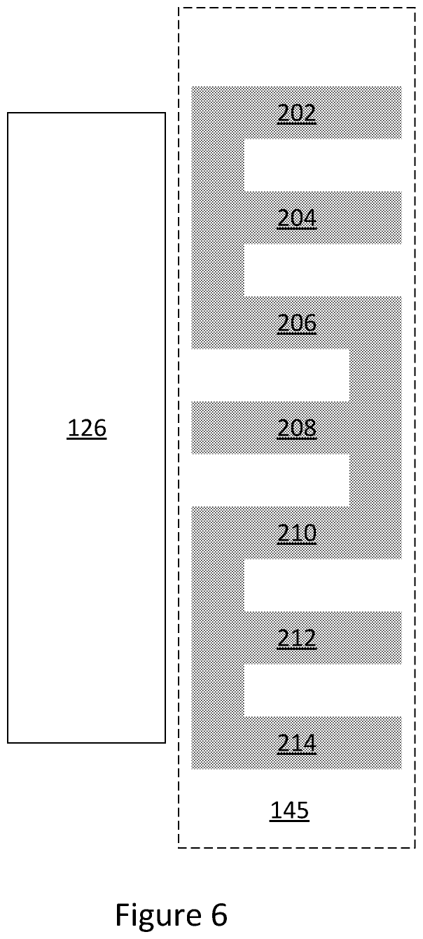

FIG. 6 illustrates a simplified top view of a fifth implementation of the field plate slit structure of the high voltage MOSFET device shown in FIG. 1 in accordance with various embodiments of the present disclosure. The field plate slit structure shown in FIG. 6 is similar to the field plate slit structure shown in FIG. 2 except that a plurality of connection bars is connected to left terminals and right terminals of the plurality of slits in an alternating manner. The configuration of the field plate slits helps to further improve the performance of the field plate slit structure. As shown in FIG. 6, a first connection bar is used to connect the left terminals of the slits 202, 204 and 206. A second connection bar is used to connect the right terminals of the slits 206, 208 and 210. A third connection bar is used to connect the left terminals of the slits 210, 212 and 214.

One advantageous feature of having the connection bars shown in FIG. 6 is that the electrically connected slits help to simplify the layout of the first metallization layer.

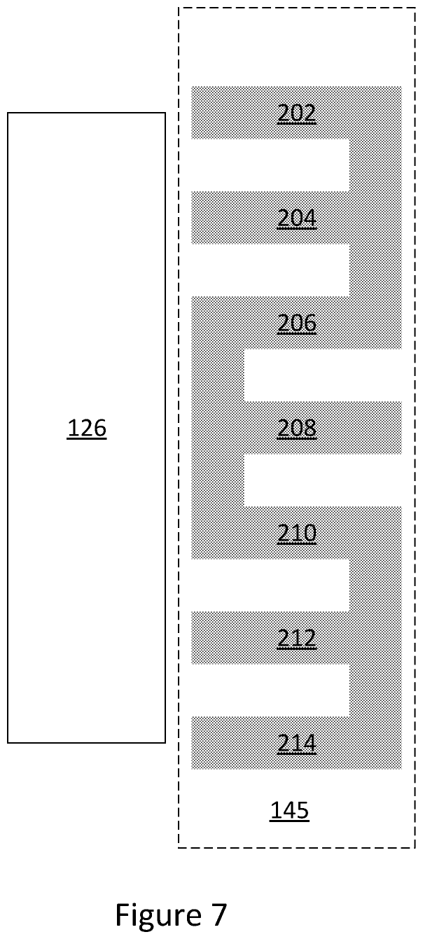

FIG. 7 illustrates a simplified top view of a sixth implementation of the field plate slit structure of the high voltage MOSFET device shown in FIG. 1 in accordance with various embodiments of the present disclosure. The field plate slit structure shown in FIG. 7 is similar to the field plate slit structure shown in FIG. 2 except that three connection bars are included to further improve the performance of the field plate slit structure. As shown in FIG. 7, a first connection bar is used to connect the right terminals of the slits 202, 204 and 206. A second connection bar is used to connect the left terminals of the slits 206, 208 and 210. A third connection bar is used to connect the right terminals of the slits 210, 212 and 214.

One advantageous feature of having the connection bars shown in FIG. 7 is that the electrically connected slits help to simplify the layout of the first metallization layer.

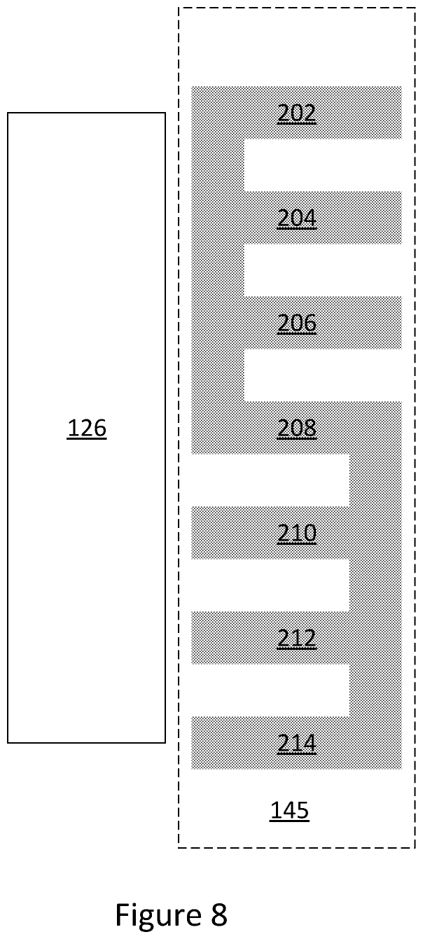

FIG. 8 illustrates a simplified top view of a seventh implementation of the field plate slit structure of the high voltage MOSFET device shown in FIG. 1 in accordance with various embodiments of the present disclosure. The field plate slit structure shown in FIG. 8 is similar to the field plate slit structure shown in FIG. 2 except that two connection bars are included to further improve the performance of the field plate slit structure. As shown in FIG. 8, a first connection bar is used to connect the left terminals of the slits 202, 204, 206 and 208. A second connection bar is used to connect the right terminals of the slits 208, 210, 212 and 214.

One advantageous feature of having the connection bars shown in FIG. 8 is that the electrically connected slits help to simplify the layout of the first metallization layer.

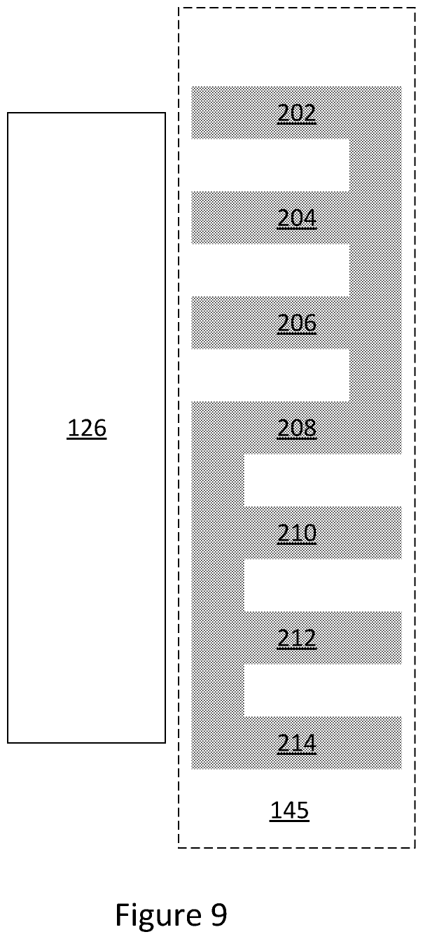

FIG. 9 illustrates a simplified top view of an eighth implementation of the field plate slit structure of the high voltage MOSFET device shown in FIG. 1 in accordance with various embodiments of the present disclosure. The field plate slit structure shown in FIG. 9 is similar to the field plate slit structure shown in FIG. 2 except that two connection bars are included to further improve the performance of the field plate slit structure. As shown in FIG. 9, a first connection bar is used to connect the right terminals of the slits 202, 204, 206 and 208. A second connection bar is used to connect the left terminals of the slits 208, 210, 212 and 214.

One advantageous feature of having the connection bars shown in FIG. 9 is that the electrically connected slits help to simplify the layout of the first metallization layer.

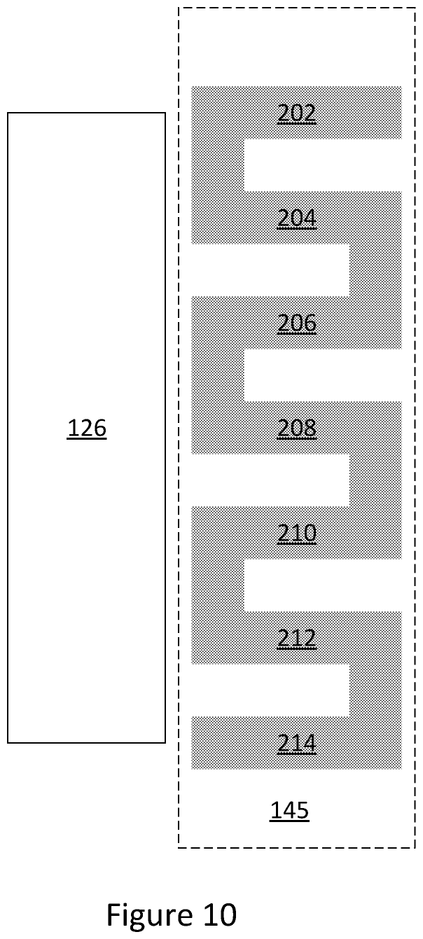

FIG. 10 illustrates a simplified top view of a ninth implementation of the field plate slit structure of the high voltage MOSFET device shown in FIG. 1 in accordance with various embodiments of the present disclosure. The field plate slit structure shown in FIG. 10 is similar to the field plate slit structure shown in FIG. 2 except that six connection bars are included to further improve the performance of the field plate slit structure. As shown in FIG. 10, a first connection bar is used to connect the left terminals of the slits 202 and 204. A second connection bar is used to connect the right terminals of the slits 204 and 206. A third connection bar is used to connect the left terminals of the slits 206 and 208. A fourth connection bar is used to connect the right terminals of the slits 208 and 210. A fifth connection bar is used to connect the left terminals of the slits 210 and 212. A sixth connection bar is used to connect the right terminals of the slits 212 and 214. As shown in FIG. 10, the six connection bars are connected to left terminals and right terminals of the seven slits in an alternating manner.

One advantageous feature of having the connection bars shown in FIG. 10 is that the electrically connected slits help to simplify the layout of the first metallization layer.

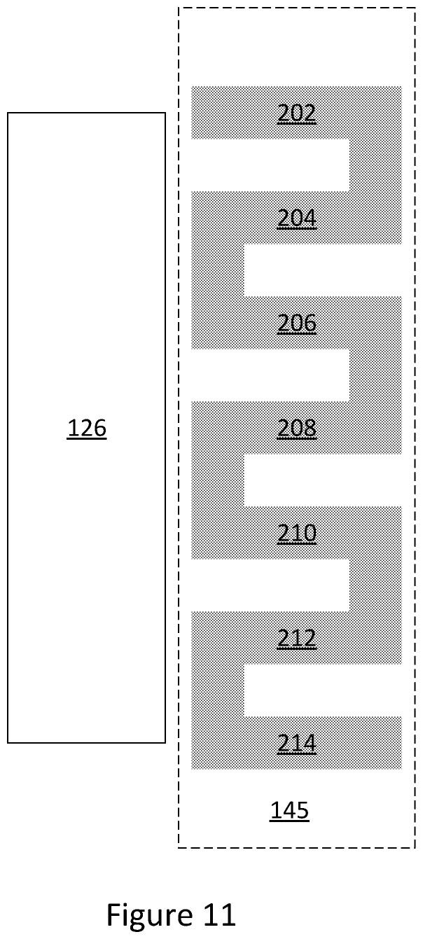

FIG. 11 illustrates a simplified top view of a tenth implementation of the field plate slit structure of the high voltage MOSFET device shown in FIG. 1 in accordance with various embodiments of the present disclosure. The field plate slit structure shown in FIG. 11 is similar to the field plate slit structure shown in FIG. 2 except that six connection bars are included to further improve the performance of the field plate slit structure. As shown in FIG. 11, a first connection bar is used to connect the right terminals of the slits 202 and 204. A second connection bar is used to connect the left terminals of the slits 204 and 206. A third connection bar is used to connect the right terminals of the slits 206 and 208. A fourth connection bar is used to connect the left terminals of the slits 208 and 210. A fifth connection bar is used to connect the right terminals of the slits 210 and 212. A sixth connection bar is used to connect the left terminals of the slits 212 and 214. As shown in FIG. 11, the six connection bars are connected to left terminals and right terminals of the seven slits in an alternating manner.

One advantageous feature of having the connection bars shown in FIG. 11 is that the electrically connected slits help to simplify the layout of the first metallization layer.

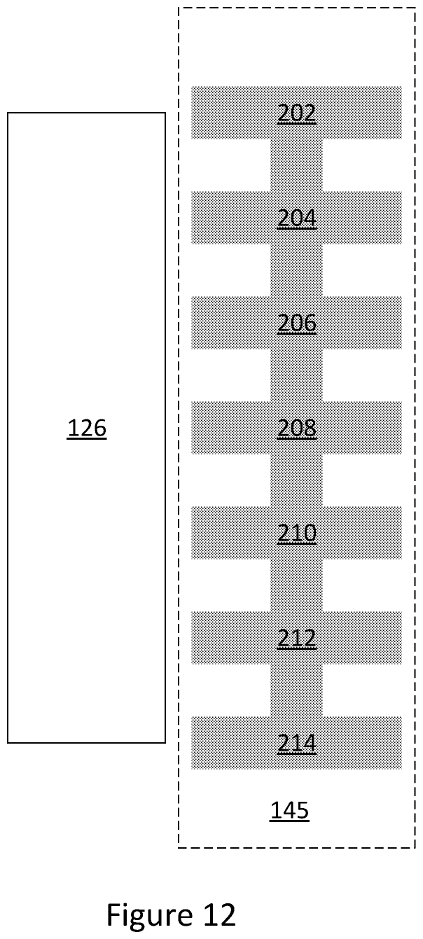

FIG. 12 illustrates a simplified top view of an eleventh implementation of the field plate slit structure of the high voltage MOSFET device shown in FIG. 1 in accordance with various embodiments of the present disclosure. The field plate slit structure shown in FIG. 12 is similar to the field plate slit structure shown in FIG. 2 except that a connection bar is included to further improve the performance of the field plate slit structure. As shown in FIG. 12, the connection bar is placed over the midpoints of the slits 202-214. The slits 202-214 are electrically connected to each other through the connection bar.

One advantageous feature of having the connection bars shown in FIG. 12 is that the electrically connected slits help to simplify the layout of the first metallization layer.

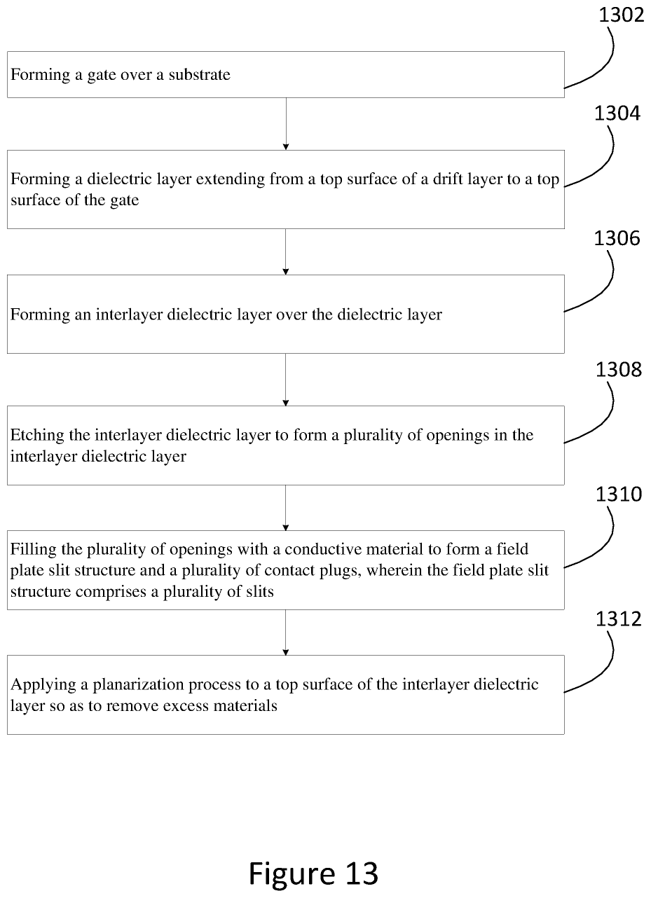

FIG. 13 illustrates a flow chart of a method for forming the high voltage MOSFET device shown in FIG. 1 in accordance with various embodiments of the present disclosure. This flowchart shown in FIG. 13 is merely an example, which should not unduly limit the scope of the claims. One of ordinary skill in the art would recognize many variations, alternatives, and modifications. For example, various steps illustrated in FIG. 13 may be added, removed, replaced, rearranged and repeated.

Referring to FIG. 1, a buried layer (e.g., a lower portion of layer 104) and an epitaxial layer (e.g., an upper portion of layer 104) are formed over a substrate (e.g., layer 102). A drift layer (e.g., layer 106) is formed over the epitaxial layer. A second drain/source region (e.g., drain region 116) is formed in the drift layer. A body region (e.g., region 112) is formed in the drift layer. A first drain/source region (e.g., source region 114) is formed in the body region. A body contact (e.g., region 118) is formed in the body region. The body contact and the first drain/source region are electrically connected to each other. A gate (e.g., gate 126) formed over the substrate and between the first drain/source region and the second drain/source region. A gate dielectric layer (e.g., layer 132) is formed underneath the gate. Gate spacers (e.g., gate spacers 125 and 127) are formed along the sidewalls of the gate. A plurality of silicide layers (e.g., silicide layers 151, 153, 134 and 157) is formed over the body contact region, the first drain/source region, the gate and the second drain/source region, respectively.

An interlayer dielectric layer (e.g., layer 140) is formed over the gate, the first drain/source region and the second drain/source region. A dielectric layer (e.g., layer 155) extends from a top surface of the drift layer to a top surface of the gate. A plurality of contact plugs (e.g., contact plugs 141, 143 and 147) and a field plate slit structure (e.g., field plate slit structure 145) are formed in the interlayer dielectric layer.

The high voltage MOSFET device shown in FIG. 1 is formed by the following steps.

At step 1302, a gate is formed over a substrate.

At step 1304, a dielectric layer is formed. The dielectric layer extends from a top surface of a drift layer to a top surface of the gate.

At step 1306, an interlayer dielectric layer is formed over the dielectric layer.

At step 1308, the interlayer dielectric layer is etched to form a plurality of openings in the interlayer dielectric layer.

At step 1310, the plurality of openings is filled with a conductive material to form a field plate slit structure and a plurality of contact plugs. The field plate slit structure comprises a plurality of slits.

At step 1312, a planarization process is applied to a top surface of the interlayer dielectric layer so as to remove excess materials.

The method further comprises growing a buried layer and an epitaxial layer on the substrate, forming the drift layer over the epitaxial layer, forming a body region in the drift layer, implanting ions to form a source region and a body contact region in the body region, and a drain region in the drift layer, wherein the body contact region and the source region are electrically connected to each other, forming a gate dielectric layer over the body region and the drift layer, and forming the gate over the gate dielectric layer.

The plurality of contact plugs comprises a source contact plug connected to the source region, a body contact plug connected to the body region and a drain contact plug connected to the drain region.

The method further comprises connecting left terminals of the plurality of slits together using a first connection bar, and connecting right terminals of the plurality of slits together using a second connection bar.

The method further comprises connecting left terminals of the plurality of slits and connecting right terminals of the plurality of slits in an alternating manner using a plurality of connection bars.

The method further comprises connecting midpoints of the plurality of slits using a connection bar.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus comprising:
a substrate of a first conductivity;
a drift layer of a second conductivity formed over the substrate;
a body region of the first conductivity formed in the drift layer;
a source region of the second conductivity formed in the body region;
a drain region of the second conductivity formed in the drift layer;
a gate dielectric layer formed over the body region and the drift layer;
a gate formed over the gate dielectric layer;
a first dielectric layer extending from a top surface of the drift layer to a top surface of the gate; and
a field plate slit structure formed over the first dielectric layer, wherein the field plate slit structure comprises a plurality of slits.

2. The apparatus of claim 1, wherein:
the plurality of slits is connected to the source region through a metal line formed over the plurality of slits.

3. The apparatus of claim 1, further comprising:
a buried layer of the second conductivity between the substrate and the drift layer;
a second dielectric layer formed over the gate; and
a source contact plug, the plurality of slits and a drain contact plug formed in the second dielectric layer, and wherein the source contact plug, the plurality of slits and the drain contact plug are formed of a same conductive material.

4. The apparatus of claim 1, further comprising:
a body contact of the first conductivity formed in the body region, wherein the body contact and the source region are electrically connected to each other.

5. The apparatus of claim 1, wherein:
the first conductivity is p-type; and
the second conductivity is n-type.

6. The apparatus of claim 1, wherein:
the first dielectric layer is a silicide block layer.

7. The apparatus of claim 1, further comprising:
a first connection bar configured to connect left terminals of the plurality of slits; and
a second connection bar configured to connect right terminals of the plurality of slits.

8. The apparatus of claim 1, further comprising:
a plurality of connection bars connected to left terminals and right terminals of the plurality of slits in an alternating manner.

9. The apparatus of claim 1, further comprising:
a connection bar over midpoints of the plurality of slits, wherein the plurality of slits is electrically connected to each other through the connection bar.

10. A method comprising:
forming a gate over a substrate;
forming a dielectric layer extending from a top surface of a drift layer to a top surface of the gate;
forming an interlayer dielectric layer over the dielectric layer;
etching the interlayer dielectric layer to form a plurality of openings in the interlayer dielectric layer;
filling the plurality of openings with a conductive material to form a field plate slit structure and a plurality of contact plugs, wherein the field plate slit structure comprises a plurality of slits; and
applying a planarization process to a top surface of the interlayer dielectric layer so as to remove excess materials.

11. The method of claim 10, further comprising:
growing a buried layer and an epitaxial layer on the substrate;
forming the drift layer over the epitaxial layer;
forming a body region in the drift layer;
implanting ions to form a source region and a body contact region in the body region, and a drain region in the drift layer, wherein the body contact region and the source region are electrically connected to each other;
forming a gate dielectric layer over the body region and the drift layer; and
forming the gate over the gate dielectric layer.

12. The method of claim 11, wherein:
the plurality of contact plugs comprises a source contact plug connected to the source region, a body contact plug connected to the body region and a drain contact plug connected to the drain region.

13. The method of claim 10, further comprising:
connecting left terminals of the plurality of slits together using a first connection bar; and
connecting right terminals of the plurality of slits together using a second connection bar.

14. The method of claim 10, further comprising:
connecting left terminals of the plurality of slits and connecting right terminals of the plurality of slits in an alternating manner using a plurality of connection bars.

15. The method of claim 10, further comprising:
connecting midpoints of the plurality of slits using a connection bar.

16. A device comprising:
a first drain/source region and a second drain/source region formed over a substrate;
a gate formed over the substrate and between the first drain/source region and the second drain/source region;
an interlayer dielectric layer formed over the gate, the first drain/source region and the second drain/source region; and
a plurality of contact plugs and a field plate slit structure formed in the interlayer dielectric layer, wherein the field plate slit structure comprises a plurality of slits.

17. The device of claim 16, further comprising:
a buried layer and an epitaxial layer over the substrate;
a drift layer over the epitaxial layer, wherein the second drain/source region is a drain region formed in the drift layer;
a body region in the drift layer, wherein the first drain/source region is in the body region; and
a body contact formed in the body region, wherein the body contact and the first drain/source region are electrically connected to each other.

18. The device of claim 16, wherein:
the plurality of slits is in parallel, and wherein:
left terminals of the plurality of slits are connected together by a first connection bar; and
right terminals of the plurality of slits are connected together by a second connection bar.

19. The device of claim 16, wherein:
the plurality of slits is in parallel, and wherein:
a plurality of first connection bars is configured to connect left terminals of the plurality of slits; and
a plurality of second connection bars is configured to connect right terminals of the plurality of slits, and wherein the plurality of first connection bars and the plurality of second connection bars are arranged in an alternating manner.

20. The device of claim 16, wherein:
the first drain/source region is a source region; and
the second drain/source region is a drain region.
